(19) United States
(12) Patent Application Publication
(10) Pub. No.: US 2024/0282603 A1
(43) Pub. Date: Aug. 22, 2024

(54) SUBSTRATE PROCESSING APPARATUS AND METHOD OF ESTIMATING FLOW RATE OF PROCESSING LIQUID FOR SUBSTRATE PROCESSING APPARATUS

(71) Applicant: Tokyo Electron Limited, Tokyo (JP)

(72) Inventors: Hiroshi MARUMOTO, Kumamoto (JP); Takashi UNO, Kumamoto (JP)

(73) Assignee: Tokyo Electron Limited, Tokyo (JP)

(21) Appl. No.: 18/413,497

(22) Filed: Jan. 16, 2024

(30) Foreign Application Priority Data
Feb. 20, 2023 (JP) 2023-023956

(51) Int. Cl. H01L 21/67

(52) U.S. Cl. CPC H01L 21/6715; H01L 21/67023; H01L 21/67051; H01L 21/67253

(57) ABSTRACT

A flow rate estimating method includes a supply process, an image process, and an estimate process. The supply process supplies processing liquid from a processing-liquid supplying unit to a position that is apart from the center of the substrate while rotating the substrate utilizing a substrate holding unit that rotatably holds the substrate. The image process images a liquid film formed by diffusion of the processing liquid on the surface of the substrate utilizing an imaging unit. The estimate process calculates a characteristic amount that indicates a state of the diffusion of the processing liquid from an imaging result of the imaging unit, and estimates the flow rate by applying the calculated characteristic amount to a correlation function that indicates the correlation between the characteristic amount and the flow rate of the processing liquid supplied to the substrate from the processing-liquid supplying unit.

### CROSS-REFERENCE TO RELATED APPLICATION

The present application claims priority to and incorporates by reference the entire contents of Japanese Patent Application No. 2023-023956 filed in Japan on Feb. 20, 2023.

### FIELD

Exemplary embodiment disclosed herein relates to a substrate processing apparatus and a method of estimating a flow rate of processing liquid for a substrate processing apparatus.

### BACKGROUND

Conventionally, there has been known a substrate processing apparatus that supplies processing liquid to a surface of a substrate such as a semiconductor wafer (see International Publication No. 2018-216476).

The present disclosure provides a technology capable of appropriately measuring flow rate of processing liquid supplied to the substrate.

A flow rate estimating method according to an embodiment of the present disclosure is a flow rate estimating method of processing liquid of a substrate processing apparatus that executes a liquid processing by supplying processing liquid on a surface of a substrate. The flow rate estimating method includes a supply process, an image process and an estimate process. The supply process supplies processing liquid from a processing-liquid supplying unit to a position that is apart from the center of the substrate while rotating the substrate utilizing a substrate holding unit that rotatably holds the substrate. The image process images a liquid film formed by diffusion of the processing liquid on the surface of the substrate utilizing an imaging unit. The estimate process calculates a characteristic amount that indicates a state of the diffusion of the processing liquid from an imaging result of the imaging unit, and estimates a flow rate by applying the calculated characteristic amount to a correlation function that indicates the correlation between the characteristic amount and the flow rate of the processing liquid supplied to the substrate from the processing-liquid supplying unit.

### SUMMARY

A method of estimating a flow rate of processing liquid for a substrate processing apparatus that executes a liquid processing by supplying processing liquid on a surface of a substrate according to one aspect of the present disclosure includes: supplying processing liquid from a processing-liquid supplying unit to a position that is apart from a center of the substrate while rotating the substrate by utilizing a substrate holding unit that holds the substrate to be rotatable; imaging a liquid film formed by a diffusion of the processing liquid on the surface of the substrate by utilizing an imaging unit; calculating a characteristic amount that indicates a state of the diffusion of the processing liquid from an imaging result of the imaging unit; and estimating the flow rate of the processing liquid by applying the characteristic amount to a correlation function that indicates a correlation between the characteristic amount and the flow rate of the processing liquid supplied to the substrate from the processing-liquid supplying unit.

### BRIEF DESCRIPTION OF DRAWINGS

FIG. 1 is a diagram illustrating a schematic configuration of a substrate processing system according to an embodiment;

FIG. 2 is a schematic diagram illustrating a configuration of a processing unit according to the embodiment;

FIG. 3 is a schematic diagram illustrating an example of an imaging unit according to the embodiment;

FIG. 4 is a flowchart illustrating procedures of a flow meter calibration processing to be executed by the processing unit according to the embodiment;

FIG. 5 is a diagram illustrating an example of a characteristic amount;

FIG. 6 is a diagram illustrating another example of the characteristic amount;

FIG. 7 is a diagram illustrating another example of the characteristic amount;

FIG. 8 is a diagram illustrating an example of a correlation function;

FIG. 9 is a flowchart illustrating an example of procedures of a process operation to be executed by the substrate processing system according to the embodiment;

FIG. 10 is a flowchart illustrating another example of procedures of the process operation to be executed by the substrate processing system according to the embodiment; and

FIG. 11 is a flowchart illustrating another example of procedures of the process operation to be executed by the substrate processing system according to the embodiment.

### DESCRIPTION OF EMBODIMENTS

An exemplary embodiment of a flow rate estimating method of processing liquid for a substrate processing apparatus and a substrate processing apparatus disclosed in the present application (hereinafter referred to as “embodiment”) will be described below in detail with reference to the accompanying drawings. In addition, the illustrative embodiment disclosed below is not intended to limit the present invention.

In the embodiment to be described below, the expressions of “constant”, “perpendicular to”, “vertical” and “parallel” may not limited to the literal meaning. In other words, the expressions of “constant”, “perpendicular to”, “vertical” and “parallel” may include a deviation caused by, for example, a manufacturing precision, an installation precision and the like.

In the referenced drawings, a rectangular coordinate system prescribed with X-axis, Y-axis and Z-axis directions may be used in such a manner that the positive Z-axis direction is oriented upward vertically to help to understand the embodiment.

Conventionally, there has been known a substrate processing apparatus that executes a liquid processing by supplying processing liquid on a surface of a substrate such as a semiconductor wafer. In a case where the actual flow rate of the processing liquid supplied to the substrate of such substrate processing apparatus is measured, it's common that an operator collects the processing liquid in a container for a weight measurement.

However, since measuring the flow rate that requires a work of collecting the processing liquid is a measuring method that depends on a skill of the operator, the measurement result may include a deviation among different operators. Accordingly, a technology that is capable of measuring properly the flow rate of the processing liquid that is supplied to the substrate has been expected.

### Summary of Substrate Processing System

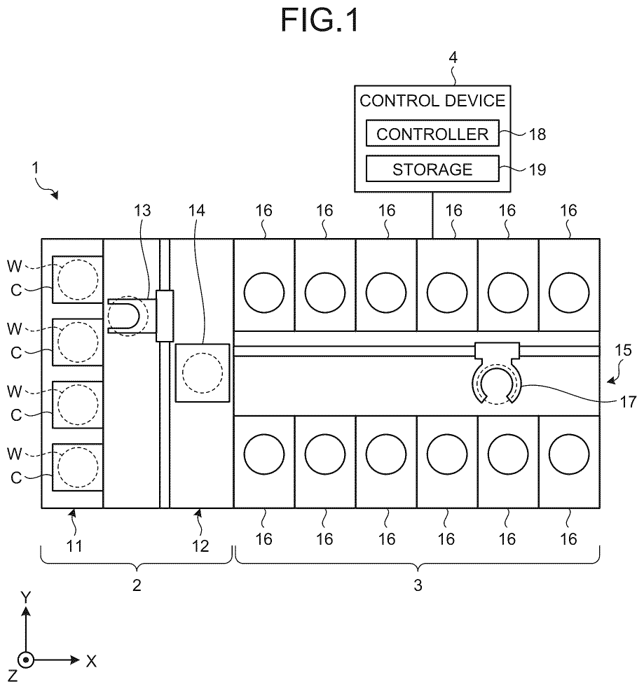

A schematic configuration of a substrate processing system 1 (one example of the substrate processing apparatus) according to the embodiment will be described with reference to FIG. 1. FIG. 1 is a diagram illustrating a schematic configuration of the substrate processing system 1 according to the embodiment.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a carrier placing section 11 and a transfer section 12. In the carrier placing section 11, a plurality of carriers C are placed to horizontally accommodate a plurality of substrates, namely, semiconductor wafers (hereinafter referred to as “wafer W”) in the embodiment.

The transfer section 12 is provided adjacent to the carrier placing section 11, and includes therein a substrate transfer device 13 and a delivery unit 14. The substrate transfer device 13 includes a wafer holding mechanism configured to hold the wafer W. The substrate transfer device 13 is movable horizontally and vertically and is pivotable around a vertical axis, and transfers the wafer W between the corresponding carrier C and the delivery unit 14 by using the wafer holding mechanism.

The processing station 3 is provided adjacent to the transfer section 12. The processing station 3 includes a transfer section 15 and a plurality of processing units 16. The plurality of processing units 16 are provided side by side at both sides of the transfer section 15.

The transfer section 15 includes therein a substrate transfer device 17. The substrate transfer device 17 includes a wafer holding mechanism configured to hold the wafer W. The substrate transfer device 17 is movable horizontally and vertically and is pivotable around the vertical axis, and transfers the wafer W between the delivery unit 14 and the corresponding processing unit 16 by using the wafer holding mechanism.

Each of the processing units 16 executes a substrate processing on the wafer W transferred by the substrate transfer device 17. The processing units 16 holds the transferred wafer W and executes the substrate processing on the wafer W. The processing units 16 supply the processing liquid on the wafer W held by the processing units and executes the substrate processing.

The processing liquid may be, but not limited to, chemical liquid such as isopropyl alcohol (IPA) and H2SO4 or rinse liquid such as deionized water (DIW).

The substrate processing system 1 further includes a control device 4. The control device 4 is, for example, a computer that includes a controller 18 and a storage 19. The storage 19 stores therein a program for controlling various types of processes to be executed in the substrate processing system 1. The controller 18 reads out and executes the program stored in the storage 19 to control operations of the substrate processing system 1.

The program may be recorded in a computer-readable recording medium and thus may be installed into the storage 19 of the control device 4 from the recording medium. The computer-readable recording medium includes, for example, a hard disk (HD), a flexible disk (FD), a compact disc (CD), a magneto-optical disk (MO), and a memory card.

In the substrate processing system 1 configured as described above, the substrate transfer device 13 of the carry-in/out station 2 first takes out the wafer W from one of the carriers C placed in the carrier placing section 11, and places the taken wafer W on the delivery unit 14. The wafer W placed on the delivery unit 14 is taken out from the delivery unit 14 by the substrate transfer device 17 of the processing station 3, and is carried into one of the processing units 16.

The wafer W carried into the processing unit 16 is processed by the processing unit 16, and then is carried out from the processing unit 16 and placed on the delivery unit 14 by using the substrate transfer device 17. Then, the processed wafer W placed on the delivery unit 14 is returned to the corresponding carrier C in the carrier placing section 11 by using the substrate transfer device 13.

### Summary of Processing Unit

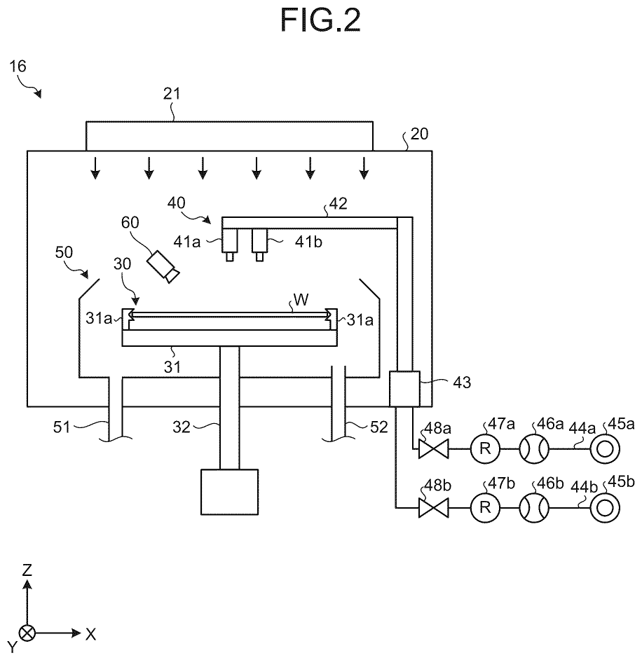

Next, a configuration of the processing unit 16 will be described with reference to FIG. 2. FIG. 2 is a diagram illustrating the configuration of the processing unit 16.

As illustrated in FIG. 2, the processing unit 16 includes a chamber 20, a substrate holding unit 30, a processing-liquid supplying unit 40, a recovery cup 50, and imaging unit 60.

The chamber 20 accommodates the substrate holding unit 30, the processing-liquid supplying unit 40, the recovery cup 50, and the imaging unit 60. A fan filter unit (FFU) 21 is provided on a ceiling of the chamber 20. The FFU 21 forms a downflow within the chamber 20.

The substrate holding unit 30 includes a holding unit 31, a supporting unit 32, and a drive unit 33. The holding unit 31 horizontally holds the wafer W. Specifically, the holding unit 31 includes a plurality of gripping units 31a to grip the an edge of the wafer W The supporting unit 32 is a vertically extending member, and includes a bottom end rotatably supported by the drive unit 33 and a leading end horizontally supporting the holding unit 31. The drive unit 33 rotates the supporting unit 32 around the vertical axis. The substrate holding unit 30 rotates the supporting unit 32 by using the drive unit 33 to rotate the holding unit 31 supported by the supporting unit 32, and consequently rotates the wafer W held on the holding unit 31.

The processing-liquid supplying unit 40 supplies various kinds of processing liquid onto the wafer W. The processing-liquid supplying unit 40 includes nozzles 41a and 41b arranged above the wafer W, an arm 42 that supports the nozzles 41a and 41b, and a moving mechanism 43 for moving the arm 42.

The nozzle 41a is connected to an IPA supply source 45a via a supply line 44a, and discharges the IPA supplied from the IPA supply source 45a on a surface of the wafer W. The IPA is one example of the processing liquid.

A flow meter 46a, a constant pressure valve 47a, and a valve 48a are provided on the supply line 44a. The flow meter 46a measures a flow rate of IPA that flows in the supply line 44a. The constant pressure valve 47a adjusts the pressure of IPA at a downstream side of the constant pressure valve 47a. For example, the constant pressure valve 47a adjusts the pressure of IPA in such a manner that a discharge amount of IPA that is discharged from the nozzle 41a of the processing-liquid supplying unit 40 becomes a predetermined discharge amount. In other words, the constant pressure valve 47a adjusts the flow rate of IPA that is discharged from the nozzle 41a of the processing-liquid supplying unit 40. The predetermined discharge amount may include a plurality of set flow rates included in a processing recipe of the liquid processing to be executed at the processing units 16. The constant pressure valve 47a adjusts the pressure of IPA, based on a signal from the control device 4, in such a manner that the flow rate of IPA measured by the flow meter 46a becomes a predetermined discharge amount. The valve 48a opens/closes the supply line 44a.

The nozzle 41b is connected to a DIW supply source 45b via a supply line 44b, and discharges the DIW supplied from the DIW supply source 45b on a surface of the wafer W. The DIW is another example of the processing liquid.

A flow meter 46b, a constant pressure valve 47b, and a valve 48b are provided on the supply line 44b. The flow meter 46b measures a flow rate of DIW that flows in the supply line 44b. The constant pressure valve 47b adjusts a pressure of DIW at a downstream side of the constant pressure valve 47b. For example, the constant pressure valve 47b adjusts the pressure of DIW in such a manner that a discharge amount of IPA that is discharged from the nozzle 41b of the processing-liquid supplying unit 40 becomes a predetermined discharge amount. In other words, the constant pressure valve 47b adjusts the flow rate of DIW that is discharged from the nozzle 41b of the processing-liquid supplying unit 40. The predetermined discharge amount may include a plurality of set flow rates included in a processing recipe of the liquid processing to be executed at the processing units 16. The constant pressure valve 47b adjusts the pressure of DIW, based on a signal from the control device 4, in such a manner that the flow rate of DIW measured by the flow meter 46b becomes a predetermined discharge amount. The valve 48b opens/closes the supply line 44b.

The recovery cup 50 is arranged to surround the holding unit 31, and collects processing liquid scattered from the wafer W due to the rotation of the holding unit 31. A drain port 51 is formed at a bottom of the recovery cup 50. The processing liquid collected by the recovery cup 50 is discharged from the drain port 51 to the outside of the processing unit 16. In addition, an exhaust port 52 is formed at the bottom of the recovery cup 50 to discharge gas supplied from the FFU 21 to the outside of the processing unit 16.

The imaging unit 60 is provided at a position where a surface of the wafer W and the processing liquid supplied on the surface of the wafer W from the processing-liquid supplying unit 40 can be imaged. The imaging unit 60 is capable of imaging a liquid film formed by diffusing the processing liquid on the surface of the wafer W. An imaging camera is used in the embodiment as one example of the imaging unit 60.

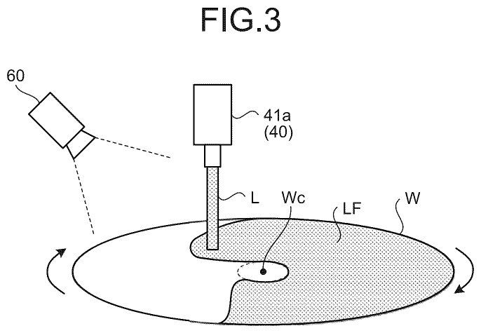

One example of the imaging unit 60 of the embodiment will now be explained. FIG. 3 is a schematic diagram illustrating an example of the imaging unit 60 according to the embodiment. As illustrated in FIG. 3, for example, in a case where processing liquid L is supplied at a position apart from the center Wc of the rotating wafer W from the processing-liquid supplying unit 40, the processing liquid L is diffused along a rotational direction of the wafer W. Accordingly, a liquid film LF is formed along the rotational direction of the wafer W on the surface of the wafer W by the diffusion of the processing liquid L. The imaging unit 60 images the liquid film LF formed by the diffusion of the processing liquid L on the surface of the wafer W.

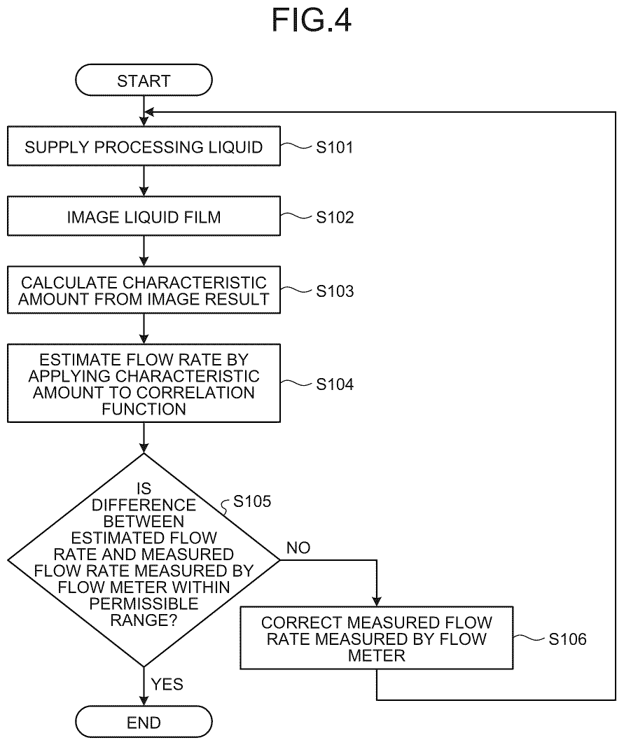

Next, one example of a flow meter calibration processing to be executed by the processing unit 16 according to the embodiment will be explained with reference to FIG. 4. FIG. 4 is a flowchart indicating procedures of the flow meter calibration processing to be executed by the processing unit 16 according to the embodiment. A series of processes of the flow meter calibration processing illustrated in FIG. 4 are executed in accordance with a control of the controller 18. It is to be noted in FIG. 4 that a flow rate of the processing liquid L supplied to the wafer W from a nozzle of one of the processing units 16 is estimated, and a series of processes for correcting a measurement value of a flowmeter corresponding to the nozzle is explained by using the estimated flow rate.

First, the controller 18 controls to hold the wafer W carried in the chamber 20 by the substrate transfer device 17 (see FIG. 1) with the holding unit 31 of the substrate holding unit 30. Specifically, the controller 18 controls in such a manner that a plurality of gripping units 31a hold an edge of the wafer W. The wafer W could be either one of a dummy wafer for the flow rate estimation or a product wafer. Then, the controller 18 controls to rotate the wafer W by rotating the holding unit 31 around the vertical axis using the drive unit 33.

The controller 18 controls to supply the processing liquid L (for example, IPA) from a nozzle (for example, nozzle 41a) of the processing-liquid supplying unit 40 to a position apart from the center Wc of the wafer W (Step S101). Accordingly, the liquid film LF (see FIG. 3) is formed on the surface of the wafer W by diffusion of the processing liquid L.

The controller 18 controls the imaging unit 60 to image the liquid film LF (Step S102). A diffusing state of the processing liquid L changes in accordance with a flow rate of the processing liquid L (for example, IPA) supplied to the wafer W from the nozzle (for example, nozzle 41a) of the processing-liquid supplying unit 40. The controller 18 calculates a characteristic amount that indicates the diffusing state of the processing liquid L from the images of the liquid film LF captured by the imaging unit 60 (Step S103). The calculation of the characteristic amount is realized by an image analysis of imaging data captured by the imaging unit 60.

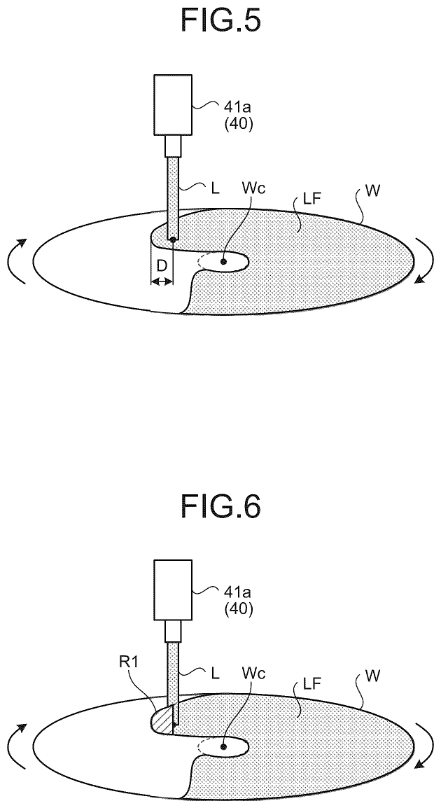

A specific example of the characteristic amount will be explained with reference to FIG. 5 to FIG. 7. FIG. 5 is a diagram illustrating an example of the characteristic amount. As illustrated in FIG. 5, the characteristic amount indicating the diffusing state of the processing liquid L can be defined, for example, as a distance D from a supply position of the processing liquid L on the surface of the wafer W to a peripheral edge of the liquid film LF (hereinafter referred to as “liquid film peripheral edge distance D”). The peripheral edge of the liquid film LF is determined as a boundary between an area where the liquid film LF exists and an area where the liquid film LF does not exist on the wafer W. The liquid film peripheral edge distance D changes in accordance with a flow rate of the processing liquid L (for example, IPA) supplied to the wafer W from the nozzle (for example, nozzle 41a) of the processing-liquid supplying unit 40. In other words, the liquid film peripheral edge distance D increases as the flow rate of the processing liquid L increases, and decreases as the flow rate of the processing liquid L decreases.

FIG. 6 is a diagram illustrating another example of the characteristic amount. As illustrated in FIG. 6, an area of the specified region R1 set on the liquid film LF can be used as the characteristic amount indicating the diffusion state of the processing liquid L. The specified region R1 is, for example, a part of the surface of the liquid film LF defined at an opposite side of the supply position of the processing liquid L with respect to the center Wc of the wafer W. The area of the specified region R1 varies in response to the flow rate of the processing liquid L (for example, IPA) that is supplied on the wafer W from the nozzle (for example, nozzle 41a) of the processing-liquid supplying unit 40. In other words, the area of the specified region R1 increases as the flow rate of the processing liquid L increases, and decreases as the flow rate of the processing liquid L decreases.

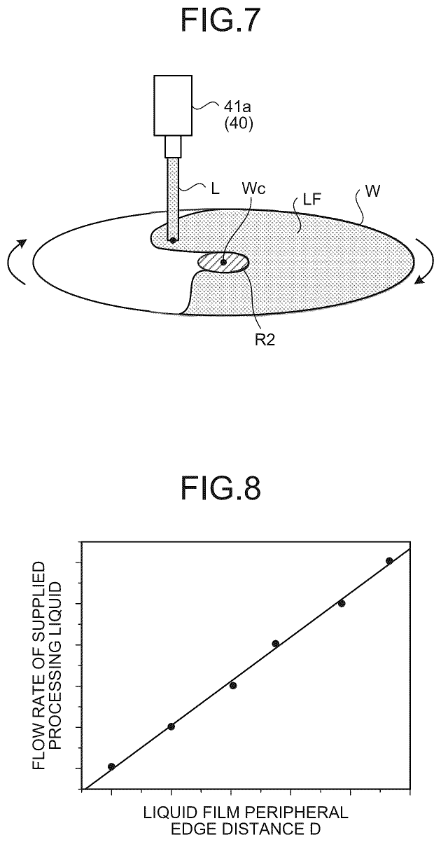

FIG. 7 is a diagram illustrating another example of the characteristic amount. As illustrated in FIG. 7, a size of the dry region R2 defined as a round region including the center Wc of the wafer W and where the liquid film LF does not exist on can be used as the characteristic amount indicating the diffusion state of the processing liquid L. For example, an area or a width (namely, diameter) of the dry region R2 can be used as the size of the dry region R2. The size of the dry region R2 varies in response to the flow rate of the processing liquid L (for example, IPA) that is supplied on the wafer W from the nozzle (for example, nozzle 41a) of the processing-liquid supplying unit 40. In other words, the size of the dry region R2 increases as the flow rate of the processing liquid L increases, and decreases as the flow rate of the processing liquid L decreases.

The characteristic amount indicating the diffusion state of the processing liquid L includes at least one of the liquid film peripheral edge distance D, the area of the specified region R1 and the size of the dry region R2.

Return to the explanation of FIG. 4. The controller 18 estimates the flow rate of the processing liquid L supplied on the wafer from the processing-liquid supplying unit 40 by applying the calculated characteristic amount to a correlation function that indicates a correlation between the characteristic amount and the flow rate of the processing liquid L supplied on the wafer W from the processing-liquid supplying unit 40 (Step S104). The correlation function that indicates the correlation between the characteristic amount and the flow rate of the processing liquid L supplied on the wafer W from the processing-liquid supplying unit 40 is stored in, for example, the storage 19 in advance. The controller 18 estimates the flow rate of the processing liquid L by applying the calculated characteristic amount to the correlation function that is stored in the storage 19.

In a case where two or more than two of the characteristic amounts among the group of the liquid film peripheral edge distance D, the area of the specified region R1 and the size of the dry region R2 are calculated, a plurality of the correlation functions that are respectively corresponding to the calculated characteristic amounts are stored in the storage 19. In this case, the controller 18 calculates an average value, as the flow rate of the processing liquid L supplied on the wafer W from the processing-liquid supplying unit 40, among a plurality of flow rates of the processing liquid L obtained by applying a plurality of calculated characteristic amounts to the plurality of correlation functions stored in the storage 19 respectively.

A specific example of the correlation function that indicates the correlation between the characteristic amount and the flow rate of the processing liquid L supplied on the wafer W from the processing-liquid supplying unit 40 will be explained with reference to FIG. 8. FIG. 8 is a diagram illustrating one example of the correlation function. FIG. 8 shows a graph obtained by imaging the liquid film LF on the surface of the wafer W as the flow rate of the processing liquid L supplied on the wafer W from the processing-liquid supplying unit 40 is varied, and measuring a plurality of the liquid film peripheral edge distance D as characteristic amounts from the imaged results of the liquid film LF for each of the flow rates.

As illustrated in FIG. 8, the liquid film peripheral edge distance D linearly increases as the flow rate of the processing liquid L increases. Accordingly, a model formula of a linear function indicating a degree of increase of the liquid film peripheral edge distance D with respect to a change of the flow rate of the processing liquid L is determined as a correlation function in advance by an experiment, a simulation or the like.

According to the embodiment, the controller 18 can properly estimate the flow rate of the processing liquid L without work of an operator by using the correlation function that indicates the correlation between the characteristic amount and the flow rate of the processing liquid L supplied on the wafer W from the processing-liquid supplying unit 40. For example, in a case where the correlation function represents a model formula of a linear function that indicates a degree of the increase of the liquid film peripheral edge distance D with respect to the flow rate of the processing liquid L, the controller 18 can estimate the flow rate of the processing liquid L by assigning the liquid film peripheral edge distance D calculated as a characteristic amount to the model formula in Step S103.

Return to the explanation of FIG. 4. The controller 18 determines whether a difference ΔD that is a difference between the estimated flow rate of the processing liquid L and the measured flow rate measured by a flow meter (for example, flow meter 46a corresponding to nozzle 41a) is within a predetermined permissible range (Step S105). The controller 18 ends the process in a case where the difference ΔD is within the predetermined permissible range (“Yes” in Step S105).

On the other hand, in a case where the difference ΔD is not within the predetermined permissible range (“No” in Step S105), the controller 18 corrects the measured flow rate measured by a flow meter (for example, the flow meter 46a corresponding to the nozzle 41a) based on the difference ΔD (Step S106), and ends the process. For example, the controller 18 corrects the measured flow rate measured by the flow meter by adding the difference ΔD to the measured flow rate measured by the flow meter. Accordingly, a deviation of the measurement value of the flow meter caused by individual differences of flow meters and the like can be canceled.

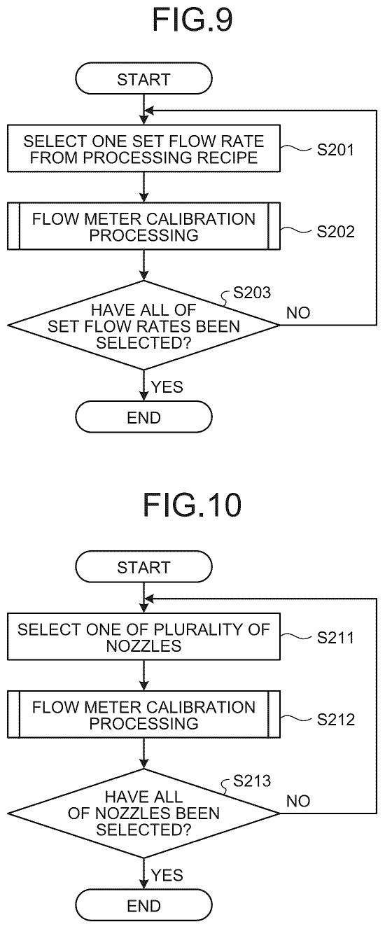

Next, procedures of a process operation to be executed by the substrate processing system 1 utilizing the flow meter calibration processing according to the embodiment will be described with reference to FIG. 9 to FIG. 11. FIG. 9 is a flowchart indicating an example of procedures of a process operation to be executed by the substrate processing system 1 according to the embodiment. Various kinds of processes illustrated in FIG. 9 are executed according to the control of the controller 18. Furthermore, the process operations illustrated in FIG. 9 may be executed at an arbitrary timing such as at a designated timing, a periodic timing and the like.

The controller 18 selects a set flow rate from a plurality of set flow rates included in a processing recipe of the liquid processing to be executed at the processing units 16 (Step S201). The processing recipe of the liquid processing is, for example, stored in the storage 19 in advance.

The controller 18 executes the flow meter calibration processing (Step S202). It's to be noted that the flow meter calibration processing is a series of processes illustrated in FIG. 4. In Step S101 of the flow meter calibration processing, the controller 18 controls to supply the processing liquid L from the nozzle of the processing-liquid supplying unit 40 with the flow rate selected in Step S201. In Step S104, the controller 18 estimates the flow rate of the processing liquid L supplied on the wafer W from the processing-liquid supplying unit 40 regarding the set flow rate selected in Step S201. In Step S106, the controller 18 corrects the measurement value measured by the flow meter by utilizing the estimated flow rate of the processing liquid L estimated regarding the set flow rate selected in Step S201.

The controller 18 determines whether all of set flow rates have been selected (Step S203), and repeats the processes of Steps S201 to S203 in a case where all of set flow rates have not been selected (“No” in Step S203). The controller 18 ends the process in a case where all of set flow rates have been selected (“Yes” in Step S203).

According to the repeat of the processes of Steps S201 to S203, the controller 18 supplies the processing liquid L from the processing-liquid supplying unit 40 for each of the plurality of set flow rates included in the processing recipe of the liquid processing. The controller 18 estimates the flow rate of the processing liquid L supplied on the wafer W from the processing-liquid supplying unit 40 for each of the plurality of set flow rates. Then, the controller 18 corrects the measurement values measured by the flow meters by utilizing the estimated flow rate of the processing liquid L for each of the plurality of set flow rates. Accordingly, a deviation of the measurement value of the flow meter caused by the flow meter for each of the plurality of set flow rates can be canceled.

FIG. 10 is a flowchart indicating another example of procedures of the process operation to be executed by the substrate processing system 1 according to the embodiment. Various kinds of processes illustrated in FIG. 10 are executed according to the control of the controller 18. Furthermore, the process operations illustrated in FIG. 10 may be executed at an arbitrary timing such as at a designated timing, a periodic timing and the like.

The controller 18 selects one of nozzles 41a and 41b of the processing-liquid supplying unit 40 (Step S211).

The controller 18 executes the flow meter calibration processing (Step S212). It's to be noted that the flow meter calibration processing is a series of processes illustrated in FIG. 4. In Step S101 of the flow meter calibration processing, the controller 18 controls to supply the processing liquid L from the nozzle selected in Step S211. In Step S104, the controller 18 estimates the flow rate of the processing liquid L supplied on the wafer W from the nozzle selected in Step S211. In Step S106, the controller 18 corrects the measurement value measured by the flow meter corresponding to the nozzle selected in Step S211.

The controller 18 determines whether all nozzles have been selected (Step S213), and repeats the processes of Steps S211 to S213 in a case where all nozzles have not been selected (“No” in Step S213). The controller 18 ends the process in a case where all nozzles have been selected (“Yes” in Step S213).

According to the repeat of the processes of Steps S211 to S213, the controller 18 supplies the processing liquid L from the nozzles 41a and 41b of the processing-liquid supplying unit 40 sequentially. The controller 18 estimates the flow rate of the processing liquid L supplied from each of the nozzles 41a and 41b. Then, the controller 18 corrects the measurement values measured by the flow meters corresponding to the nozzles 41a and 41b. Accordingly, a deviation of the measurement value of the flow meter for each of the nozzles of the processing-liquid supplying unit 40 can be canceled.

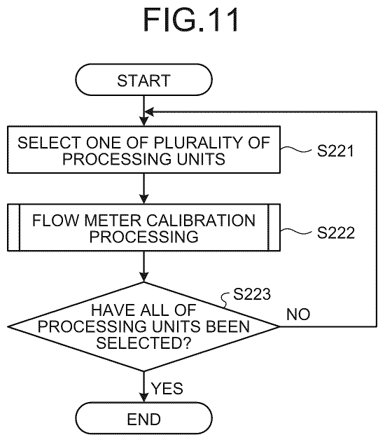

FIG. 11 is a flowchart indicating another example of procedures of the process operation to be executed by the substrate processing system 1 according to the embodiment. Various kinds of processes illustrated in FIG. 11 are executed according to the control of the controller 18. Furthermore, the process operations illustrated in FIG. 11 may be executed at an arbitrary timing such as at a designated timing, a periodic timing and the like.

The controller 18 selects one of the plurality of the processing units 16 (Step S221).

The controller 18 executes the flow meter calibration processing (Step S222). It's to be noted that the flow meter calibration processing is a series of processes illustrated in FIG. 4. In Step S101 of the flow meter calibration processing, the controller 18 controls to supply the processing liquid L from a processing-liquid supplying unit 40 of the selected processing unit 16 in Step S221. In Step S104, the controller 18 estimates the flow rate of the processing liquid L supplied on the wafer W from the processing-liquid supplying unit 40 of the processing unit 16 selected in Step S221. In Step S106, the controller 18 corrects the measurement value measured by the flow meter corresponding to the processing-liquid supplying unit 40 of the processing unit 16 selected in Step S221.

The controller 18 determines whether all of the processing units 16 have been selected (Step S223), and repeats the processes of Steps S221 to S223 in a case where all of the processing units 16 have not been selected (“No” in Step S223). The controller 18 ends the process in a case where all of the processing units 16 have been selected (“Yes” in Step S223).

According to the repeat of the processes of Steps S221 to S223, the flow meter calibration processing is executed for each of the processing units 16 in turn. Accordingly, a deviation of the measurement value of the flow meter for each of the processing units 16 can be canceled.

As described above, the flow rate estimating method according to the embodiment is a flow rate estimating method of processing liquid of a substrate processing apparatus (substrate processing system 1 as one example) that executes a liquid processing by supplying processing liquid (processing liquid L as one example) on a surface of a substrate (wafer W as one example). The flow rate estimating method includes a supply process, an image process and an estimate process. The supply process supplies processing liquid from a processing-liquid supplying unit (processing-liquid supplying unit 40 as one example) to a position that is apart from the center of the substrate while rotating the substrate utilizing a substrate holding unit (substrate holding unit 30 as one example) that rotatably holds the substrate. The image process images a liquid film (liquid film LF as one example) formed by diffusion of the processing liquid on the surface of the substrate utilizing an imaging unit (imaging unit 60 as one example). The estimate process calculates a characteristic amount that indicates a state of the diffusion of the processing liquid from an imaging result of the imaging unit, and estimates a flow rate by applying the calculated characteristic amount to a correlation function that indicates the correlation between the characteristic amount and the flow rate of the processing liquid supplied to the substrate from the processing-liquid supplying unit. According to the flow rate estimating method according to the embodiment, it may be possible to appropriately estimate the flow rate of the processing liquid supplied to the substrate.

The substrate processing apparatus may include supply lines (supply lines 44a, 44b as one example) and flow meters (flow meters 46a, 46b as one example) that are provided on the supply lines to measure the flow rate of the processing liquid in the supply lines. Furthermore, the flow rate estimating method according to the embodiment may include a process for correcting a measurement value of the flow meter on the basis of the difference between the estimated flow rate of the processing liquid estimated by the estimate process and the measurement value of the flow meter. According to the flow rate estimating method of the embodiment, a deviation of the measurement value of the flow meter caused by individual difference of the flow meter and the like can be canceled.

The supply process may supply processing liquid from the processing-liquid supplying unit with a plurality of different set flow rates included in the processing recipe of the liquid processing. The estimate process may estimate the flow rate of the processing liquid supplied to the substrate from the processing-liquid supplying unit for each of the plurality of set flow rates. The process for correcting the measurement value may correct the measurement value of the flow meter by utilizing the value of the flow rate of the processing liquid estimated for each of the plurality of set flow rates. According to the flow rate estimating method of the embodiment, a deviation of the measurement value of the flow meter for each of the set flow rates included in the processing recipe can be canceled.

The processing-liquid supplying unit may include a plurality of nozzles (nozzles 41a, 41b as one example) for discharging different processing liquids, a plurality of supply lines (supply lines 44a, 44b as one example) for supplying the processing liquids to each of the plurality of nozzles, and a plurality of flow meters (flow meters 46a, 46b as one example) that are provided on the plurality of supply lines respectively. The supply process may supply processing liquids from the plurality of nozzles sequentially. The estimate process may estimate flow rates of the processing liquids supplied to the substrate from each of the plurality of nozzles. The process for correcting the measurement value may correct measurement values of the flow meters corresponding to each of the plurality of nozzles. According to the flow rate estimating method of the embodiment, a deviation of the measurement value of the flow meter corresponding to each of the nozzles can be canceled.

Furthermore, the substrate processing apparatus may execute the liquid processing for a plurality of substrates by utilizing a plurality of processing units (processing units 16 as one example) each of which includes the substrate holding unit, the processing-liquid supplying unit, the imaging unit, the supply line, and the flow meter. The supply process, the image process, estimate process, and the process for correcting the measurement value may be executed for each of the processing units. According to the flow rate estimating method of the embodiment, a deviation of the measurement value of the flow meter for each of the processing units can be canceled.

The characteristic amount includes at least one of the distance from the supply position of the processing liquid on the surface of the substrate to the peripheral edge of the liquid film (liquid film peripheral edge distance D as one example), the area of the specified region set on the liquid film (specified region R1 as one example), and the size of the dry region (dry region R2 as one example) that is defined as a region including the center of the surface of the substrate and where the liquid film does not exist. According to the flow rate estimating method according to the embodiment, it may be possible to appropriately estimate the flow rate of the processing liquid supplied to the substrate.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

According to the present disclosure, it may be possible to appropriately measure the flow rate of processing liquid supplied to a substrate.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method of estimating a flow rate of processing liquid for a substrate processing apparatus that executes a liquid processing by supplying processing liquid on a surface of a substrate, the method comprising:
supplying processing liquid from a processing-liquid supplying unit to a position that is apart from a center of the substrate while rotating the substrate by utilizing a substrate holding unit that holds the substrate to be rotatable;
imaging a liquid film formed by a diffusion of the processing liquid on the surface of the substrate by utilizing an imaging unit;
calculating a characteristic amount that indicates a state of the diffusion of the processing liquid from an imaging result of the imaging unit; and
estimating the flow rate of the processing liquid by applying the characteristic amount to a correlation function that indicates a correlation between the characteristic amount and the flow rate of the processing liquid supplied to the substrate from the processing-liquid supplying unit.

2. The method according to claim 1, wherein
the substrate processing apparatus includes:
a supply line that supplies the processing liquid to the processing-liquid supplying unit; and
a flow meter provided on the supply line that measures the flow rate of the processing liquid in the supply line, and
the method further comprises:
correcting a measurement value of the flow meter based on a difference between the estimated flow rate of the processing liquid and the flow rate measured by the flow meter.

3. The method according to claim 2, wherein
supplying processing liquid further includes supplying liquid from the processing-liquid supplying unit with a plurality of different set flow rates included in a processing recipe of the liquid processing,
estimating the flow rate further includes:
estimating the flow rate of the processing liquid supplied to the substrate from the processing-liquid supplying unit for each of the plurality of set flow rates; and
correcting the measurement value further includes correcting the measurement value of the flow meter by utilizing the flow rate of the processing liquid estimated for each of the plurality of set flow rates.

4. The method according to claim 2, wherein
the processing-liquid supplying unit further includes a plurality of nozzles for discharging different processing liquids, a plurality of supply lines for supplying the processing liquids to the plurality of nozzles respectively, and a plurality of flow meters that are provided on the plurality of supply lines respectively,
supplying processing liquid further includes sequentially supplying the processing liquids from the plurality of nozzles,
estimating the flow rate includes estimating flow rates of the processing liquids supplied to the substrate from each of the plurality of nozzles, and
correcting the measurement value includes correcting measurement values of the respective flow meters corresponding to the plurality of nozzles.

5. The method according to claim 2, wherein
the substrate processing apparatus includes a plurality of processing units each of which includes the substrate holding unit, the processing-liquid supplying unit, the imaging unit, the supply line, and the flow meter,
the method includes executing the liquid processing on surfaces of a plurality of substrates by using the plurality of processing units, and
supplying processing liquid, imaging the liquid film, estimating the flow rate, and correcting the measurement value are individually executed for each of the plurality of processing units.

6. The method according to claim 1, wherein
the characteristic amount includes at least one of distance from a supply position of the processing liquid on the surface of the substrate to a peripheral edge of the liquid film, an area of a specified region set on the liquid film, and a size of a dry region that is defined as a region including a center of the surface of the substrate and where the liquid film does not exist.

7. A substrate processing apparatus that supplies processing liquid on a surface of a substrate to execute liquid processing, the apparatus comprising:
a substrate holding unit that holds the substrate to be rotatable;
a processing-liquid supplying unit that supplies processing liquid on the substrate;
an imaging unit that is capable of imaging the surface of the substrate and the processing liquid supplied from the processing-liquid supplying unit on the surface of the substrate; and
a controller that controls the substrate holding unit, the processing-liquid supplying unit, and the imaging unit, wherein
the controller is configured to:
supply processing liquid from the processing-liquid supplying unit to a position that is apart from a center of the substrate while rotating the substrate utilizing the substrate holding unit;
image a liquid film formed by a diffusion of the processing liquid on the surface of the substrate by utilizing the imaging unit;
calculate a characteristic amount that indicates a state of the diffusion of the processing liquid from an imaging result of the imaging unit; and
estimate a flow rate of the processing liquid by applying the characteristic amount to a correlation function that indicates a correlation between the characteristic amount and the flow rate of the processing liquid supplied to the substrate from the processing-liquid supplying unit.
